(19) United States
(12) Patent Application Publication
(10) Pub. No.: US 2026/0005034 A1
(43) Pub. Date: Jan. 1, 2026

(54) METHOD AND APPARATUS FOR ETCHING A SURFACE

(71) Applicant: ASM IP Holding B.V., Almere (NL)

(72) Inventors: Matthew Surman, Helsinki (FI); Mikhail Krishtab, Bertem (BE); Elisa K. Atosuo, Espoo (FI); Tao Xu, Helsinki (FI); Elina Färm, Helsinki (FI); Charles Dezelah, Helsinki (FI); Patricio Eduardo Romero, Boutersem (BE)

(21) Appl. No.: 19/250,048

(22) Filed: Jun. 25, 2025

Related U.S. Application Data
(60) Provisional application No. 63/665,206, filed on Jun. 27, 2024.

(51) Int. Cl. H01L 21/3213; H01L 21/67

(52) U.S. Cl. CPC H01L 21/32135; H01L 21/67069

(57) ABSTRACT

Methods and related systems for etching. Embodiments of the present disclosure comprise etching an etchable layer by executing a cyclical etching process comprising a plurality of etching cycles. Ones from the plurality of etching cycles comprise a volatilization reactant pulse that comprises exposing a substrate to a volatilization reactant.

### CROSS-REFERENCE TO RELATED APPLICATION(S)

This application claims the benefit of U.S. Provisional Application 63/665,206 filed on Jun. 27, 2024, the entire contents of which are incorporated herein by reference.

### FIELD OF INVENTION

The present disclosure is in the field of integrated circuit processing, and particularly in the field of etching unit steps for integrated circuit manufacture.

### BACKGROUND OF THE DISCLOSURE

The patterning of metal interconnects and diffusion barriers is a crucial part of the manufacturing process. Current industry standard is the damascene process, where gaps for Cu interconnects are overfilled and the extraneous material is removed with chemical mechanical polishing. This process is limited to planar processing. Patterning by direct material removal of metals most often uses wet etching methods and plasma-based reactive ion etching (RIE). The use of plasma can cause damage to the unetched layer and surrounding materials through embedding of energetic ions to the material. RIE is also characterized as an anisotropic etching method, which limits its use for etching non-line-of-sight features.

Thermal atomic layer etching is an isotropic gas phase etching method which avoids plasma damage by using thermally activated chemical reactions for the etching. It is based on self-limiting chemical modification of the surface to be etched followed by volatilization of the modified surface layer. This enables conformal and highly controlled etching of materials.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Disclosed herein is an embodiment of etching, comprising providing a substrate to a reaction chamber, the substrate comprising an etchable layer, the etchable layer comprising a transition metal; executing a cyclical etching process comprising a plurality of etching cycles, at least one of the etching cycles comprising a oxidation reactant pulse that comprises exposing the substrate to a oxidation reactant; at least one of the etching cycles further comprising a volatilization reactant pulse that comprises exposing the substrate to a volatilization reactant; thereby etching the etchable layer; wherein the volatilization reactant is free from metals.

In some embodiments, the substrate further comprises a second layer, and wherein the second layer is not substantially etched during the cyclical etching process, thus selectively etching the etchable layer versus the second layer.

In some embodiments, the second layer comprises dielectric material.

In some embodiments, the cyclical etching process is carried out thermally.

In some embodiments, the oxidation reactant comprises O₂, O₃ or air.

In some embodiments, the volatilization agent comprises a halide.

In some embodiments, the volatilization agent comprises chlorine.

In some embodiments, the volatilization agent comprises thionyl chloride (SOCl₂).

In some embodiments, the volatilization agent comprises phosphorous trichloride (PCl₃).

In some embodiments, the etchable layer comprises metallic transition metal.

In some embodiments, the transition metal comprises at least one of molybdenum and tungsten.

In some embodiments, the cyclical etching process is carried out at a temperature of at least 250 to at most 450° C.

In some embodiments, the volatilization reactant pulse is followed by a first purge.

In some embodiments, the oxidation reactant pulse is followed by a second purge.

In some embodiments, the etching is atomic layer etching.

Further described herein is a method of etching a surface, the method comprising providing a substrate into a reaction chamber, the surface of the substrate comprising an etchable layer; and providing a volatilization reactant into the reaction chamber, wherein the etchable layer comprises MOx, where M is transition metal.

In some embodiments, the etchable layer comprises native oxide.

Further described herein is a system comprising a reaction chamber, a substrate support, and a controller, the controller being configured for causing the system to execute a method as described herein.

In some embodiments, the system does not comprise a plasma source.

### BRIEF DESCRIPTION OF THE DRAWING FIGURES

FIG. 1 shows embodiments of method according to the present disclosure.

FIG. 2 shows a structure according to the present disclosure.

FIG. 3 shows an embodiment of a system according to the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

In some embodiments, terms such as “etchant reactant”, “reactant”, and “etchant” can refer generally to at least one compound that participates in etching reaction that etches a target layer on a substrate.

In some embodiments, “layer” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may be established based on physical, chemical, and/or any other characteristics, formation process or sequence, and/or functions or purposes of the adjacent films or layers.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include noble gasses such as helium, argon, and any combination thereof. In some cases, an inert gas can include nitrogen and/or hydrogen. Purge gasses can comprise inert gasses.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In some embodiments, the term “atomic layer etching” can refer to an etching process which enables the controlled removal of material from a substrate, layer-by-layer, where the etch thickness is on the order of magnitude of a monolayer. Self-limited reaction is a key characteristic of atomic scale etching. Ideally with atomic layer etching, adsorption and desorption steps are self-limited at a maximum rate equivalent to 1 monolayer per cycle. The total amount of material removed is determined by the number of repeated cycles.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

Described herein are methods of etching. In some embodiments, presently disclosed methods comprise pulsed etching. In some embodiments, presently disclosed methods comprise atomic layer etching. An embodiment of the presently disclosed methods comprises providing a substrate to a reaction chamber. The substrate comprises an etchable layer. The etchable layer comprises a transition metal. A method according to an embodiment of the present disclosure comprises executing a cyclical etching process. The cyclical etching process comprises a plurality of etching cycles. At least one of the etching cycles comprise an oxidation reactant pulse that comprises exposing the substrate to an oxidation reactant. At least one of the etching cycles comprises a volatilization reactant pulse that comprises exposing the substrate to a volatilization reactant. The volatilization reactant is free from metals. Thus, the etchable layer is etched.

The oxidation reactant oxidates a surface of the etchable layer. The resulting oxidized surface is then etched by contacting the surface with the volatilization reactant. Doing so sequentially allows digitally etching the etchable layer.

In some embodiments, the oxidation reactant pulse precedes the volatilization reactant pulse. In some embodiments, the volatilization reactant pulse precedes the oxidation reactant pulse.

It shall be understood that in some embodiments, the oxidation reactant pulse and the volatilization reactant pulse are at least partially non-overlapping. In some embodiments, the oxidation reactant pulse and the volatilization reactant pulse do not overlap. In some embodiments, adjacent oxidation reactant pulses and volatilization reactant pulses are separated by purges.

While the presently disclosed methods are generally described as a cyclical processes, co-flow of oxidation reactant and volatilization reactant can be done too, in some embodiments. In other words, in some embodiments, oxidation reactant and volatilization reactant are provided together to the reaction chamber. This can advantageously enhance throughput though such processes do not feature self-limiting steps.

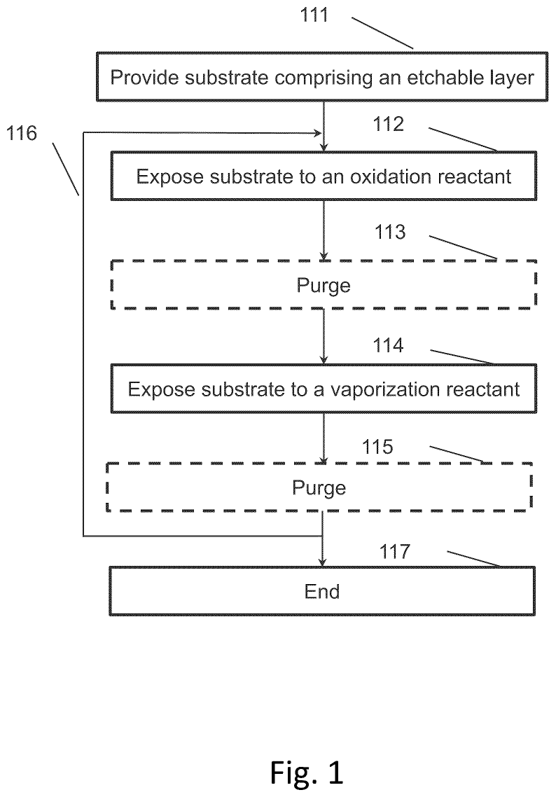

Referring to FIG. 1, described herein is an embodiment of a method according to the present disclosure. The method comprises a step 111 of providing a substrate to a reaction chamber. Then, the method comprises optionally executing a plurality of etching cycles 116. Ones from the plurality of etching cycles comprise, in the order given, a step 112 of exposing the substrate to an oxidation reactant, an optional purge 113, a step 114 of exposing the substrate to a volatilization reactant, and another optional purge 115. Alternatively, the step of exposing the step 112 of exposing the substrate to an oxidation reactant can be preceded by the step 114 of exposing the substrate to a volatilization reactant as described herein. The cycles can be optionally repeated 116. After a suitable amount of etching cycles have been carried out, the method ends.

The various process steps of the etch cycle discussed above may be sequentially repeated to remove a targeted thickness of etchable from the surface of the substrate. As an example, referring to the embodiment shown in FIG. 1, the method may comprise repeating steps 112 and 114 one or more (n) times to remove a targeted thickness of etchable layer from the surface of the substrate. Other steps may be inserted in the process as needed. For example, other reaction steps and/or etching steps may be performed before or after or between the n repeating cycles. The number of repeated cycles (n) is not particularly limited and depends upon the targeted etchable layer thickness that is to be removed and the etch rate of etchable layer. In some embodiments, the etchable layer is etched at a rate from about 0.1 Å to about 15 Å per etch cycle, such as at a rate from about 0.1 Å to about 10 Å per etch cycle, or even at a rate from about 0.3 Å to about 5 Å per etch cycle. In some embodiments, the etchable layer is etched at a rate from about 0.1 Å to about 5 Å per etch cycle, or at a rate from about 0.2 Å to about 0.5 Å per etch cycle, or at a rate from about 0.3 Å to about 0.5 Å per etch cycle. In some embodiments, the process is repeated until a targeted thickness of the etchable layer has been removed. In some embodiments, the process is repeated until the entire etchable layer has been removed. In some embodiments, the etchable layer may have an initial thickness (pre-etch) of between about 0.5 nm and about 20 nm, or between about 2 nm and about 15 nm, or between about 4 nm and about 15 nm. In some embodiments, the etchable layer may have an initial thickness (pre-etch) of less than about 20 nm, or less than about 15 nm, or less than about 12 nm, or less than about 10 nm, or less than about 8 nm, or less than about 4 nm, or less than about 2 nm. In some embodiments, the number of repeated cycles (n) is between about 1 and about 5,000, between about 1 and about 2,000, between about 1 and about 1,000, between about 1 and about 500, between 1 and about 200, between about 1 and about 100, or typically between about 10 and about 1,000, typically between about 10 and about 500, typically between about 10 and about 200, typically between about 10 and about 100, or more typically between about 50 and about 1,000, or more typically between about 50 and about 500, or more typically between about 50 and about 200. In some embodiments, only one cycle is performed. In some embodiments, a single cycle comprises single a long oxidation pulse and a single volatilization reactant pulse.

In some embodiments, step 114 of exposing the substrate to a vaporization reactant is performed before step 112 of exposing the substrate to an oxidation reactant. In some embodiments, the substrate may have native oxide on its surface which is removed first by exposing it to at least one pulse of a vaporization reactant. In some embodiments the amount of pulses is 5 to 100 pulses of vaporization reactant. In some embodiments, the amount of pulses is 10 to 100 pulses of vaporization reactant. In some embodiments, the pulse time of pulses of vaporization reactant are 0.1 to 1 seconds. In some embodiments, there is a purge 115 after each pulse of vaporization reactant 114. In some embodiments, the purge time is 0.1 to 1 seconds.

Described herein is an embodiment of a method of selectively etching. The method comprises providing a substrate to a reaction chamber. The substrate comprises an etchable layer. The etchable layer can comprise a transition metal. The substrate further comprising a second layer. The method further comprises executing an etching process that comprises sequentially exposing the substrate to an oxidation reactant and to a vaporization reactant. Thus, the etchable layer is etched while the second layer is not substantially etched during the cyclical etching process.

In some embodiments, the second layer comprises a dielectric material. In some embodiments, the dielectric material is a silicon-containing material.

In some embodiments, the volatilization reactant is free from metals. In some embodiments, the volatilization reactant comprises a halide. In some embodiments, the halide is selected from fluoride, chloride, bromide and iodide.

In some embodiments, the volatilization reactant comprises at least one element selected from the group consisting of phosphorous, sulfur, nitrogen, oxygen, carbon, hydrogen and selenium. In some embodiments, the volatilization reactant comprises phosphorous or sulfur.

In some embodiments, the volatilization reactant comprises thionyl chloride (SOCl₂). In some embodiment, the volatilization reactant comprises phosphorous trichloride (PCl₃).

In some embodiments, the oxidation reactant comprises an oxygen reactant. An oxygen reactant can comprise oxygen.

In some embodiments, the oxygen reactant comprises O₂. In some embodiments, the oxygen reactant is selected from the list consisting of H₂O, N₂O, O₂ and O₃.

In some embodiments, the oxygen reactant is selected from the list consisting of H₂O, H₂O₂, N₂O, NO, NO₂, NO₃, CO, CO₂, O₂, air and O₃.

In some embodiments, the oxygen reactant comprises an alcohol. The alcohol can comprise one or more alcohol groups. In some embodiments, the oxygen reactant comprises a C1 to C6 linear or branched alcohol, such as methanol, ethanol, isopropanol, and n-butanol. In some embodiments, the oxygen reactant comprises a C1 to C6 linear or branched diol, such as ethane-1,2-diol.

In some embodiments, the etchable layer comprises at least 90, 95, 98, 99, 99.5, 99.8, or 99.9 atomic percent of the metal.

In some embodiments, the etchable layer substantially consists of the metal.

In some embodiments, the metal comprises a transition metal.

In some embodiments, the etchable layer comprises one or more of a transition metal nitride, boride, and phosphide. In some embodiments, the etchable layer comprises metallic transition metal. In some embodiments, the etchable layer comprises an etchable material that can be oxidized using an oxygen reactant, such as an oxygen reactant mentioned in the present disclosure.

In some embodiments, the transition metal comprises a group 3 to 7 transition metal. In some embodiments, the transition metal comprises a group 5 to 7 transition metal. In some embodiments, the transition metal comprises a group 6 transition metal. In some embodiments, the transition metal comprises at least one of molybdenum and tungsten. Suitably, the transition metal can form a volatile compound with the volatilization reactant. Possible volatile compounds include chlorides and oxychlorides.

In some embodiments, the cyclical etching process is carried out thermally. In other words, and in some embodiments, the cyclical etching process does not involve generating a plasma or exposing the substrate to plasma-generated species.

In some embodiments, the substrate further comprises a second layer. In some embodiments, the second layer is not substantially etched during the cyclical etching process. In some embodiments, the second layer is etched slower than the etchable layer. In some embodiments, the etchable layer is etched at least 2 times faster than the second layer. In some embodiments, the etchable layer is etched at least 5 times faster than the second layer. In some embodiments, the etchable layer is etched at least 10 times faster than the second layer. In some embodiments, the etchable layer is etched at least 20 times faster than the second layer. In some embodiments, the etchable layer is etched at least 50 times faster than the second layer. In some embodiments, the etchable layer is etched at least 100 times faster than the second layer.

In some embodiments, the second layer comprises a dielectric material. In some embodiments, the second layer comprises a silicon-containing material. In some embodiments, the silicon-containing material is selected from the list comprising silicon, silicon oxide, silicon nitride, silicon carbide and silicon oxycarbide. In some embodiments, the second layer comprises a material that forms a non-volatile material when exposed to the volatilization reactant. In some embodiments, the second layer comprises a material that is substantially unreactive with the volatilization reactant. In some embodiments, the second layer comprises a material that forms a passive layer when exposed to the volatilization reactant.

A cyclical etching process according to an embodiment of the present disclosure can be carried out at any suitable temperature. In some embodiments, the cyclical etching process is carried out at a temperature of at least 250 to at most 450° C., or of at least 200 to at most 500° C.

In some embodiments, the cyclical etching process is carried out at a pressure of at least 0.01 mbar to at most 1 bar, or at a pressure of at least 0.1 mbar to at most 0.1 bar, or at a pressure of at least 1 mbar to at most 10 mbar. In some embodiments, the cyclical etching process is carried out at a pressure of 10 mbar.

In some embodiments, the etch rate (etch per cycle) can be controlled by changing the temperature and pressure within the reaction chamber. In higher temperatures, the etch rate increases and in lower temperatures the etch rate decreases. By controlling the temperature the thickness of the etchable layer can easily be controlled.

In some embodiments, the temperature and pressure affect the decomposition of the volatilization reactant. In high temperature and pressure the volatilization reactant might decompose to cause spontaneous etching of the etchable layer, which may cause too much material to be etched. If the temperature and pressure are too low, no etch may occur. For ideal etching, the pressure is kept low and the pressure is increased.

In some embodiments, the volatilization reactant is stored in a reactant source comprising a heating element. In other words, and in some embodiments, the volatilization reactant can be stored in a heated source. For example, the heated source may be maintained at a temperature of at least 20° C. to at most 200° C., or of at least 60° C. to at most 150° C., or of at least 70° C. to at most 100° C., e.g. at a temperature of 80° C.

In some embodiments, the volatilization reactant pulse is followed by a by a first purge.

In some embodiments, the oxidation reactant pulse is followed by a second purge.

Purges can comprise contacting the substrate with an inert gas. Purges can be effected by alternating gas flows, or by moving the substrate through an inert gas curtain.

In some embodiments, purging can comprise subjecting the substrate to a constant flow of inert gas. During a volatilization reactant pulse, the inert gas stream can be routed through a volatilization reactant source to entrain volatilization reactant. During an oxidation reactant pulse, the inert gas stream can be routed through a conversion reactant source to entrain conversion reactant. During purges, the inert gas stream can bypass the reactant sources such that no reactant is entrained. Suitable inert gas streams can comprise a noble gas such as He, Ne, Ar, Xe, or Kr. In some embodiments, the inert gas stream comprises N₂.

In some embodiments, the pulse time of the oxidizing reactant is 0.5 to 60 seconds, preferably 0.5 to 10 seconds, such as 1 to 4 seconds, for example 2 to 3 seconds. In some embodiments, the pulse time of the oxidizing reactant is about 1 second, or about 2 seconds, or about 3 seconds.

In some embodiments, the pulse time of the volatilization reactant is 0.5 to 60 seconds, preferably 0.5 to 5 seconds, such as 1 to 4 seconds, for example 2 to 3 seconds. In some embodiments, the pulse time of the volatilization reactant is about 1 second, or about 2 seconds, or about 3 seconds.

In some embodiments, the purge time after the oxidizing reactant is 0.5 to 5 seconds, such as 1 to 4 seconds, for example 2 to 3 seconds. In some embodiments, the purge time after the oxidizing reactant is about 1 second, or about 2 seconds, or about 3 seconds.

In some embodiments, the purge time after the volatilization reactant is 0.5 to 60 seconds, preferably 0.5 to 10 seconds, such as 1 to 4 seconds, for example 2 to 3 seconds. In some embodiments, the purge time after the volatilization reactant is about 1 second, or about 2 seconds, or about 3 seconds.

Further described herein is a system that comprises a reaction chamber, a substrate support, and a controller. The controller is configured for causing the system to execute a method as described herein. In some embodiments, the system does not comprise a plasma source.

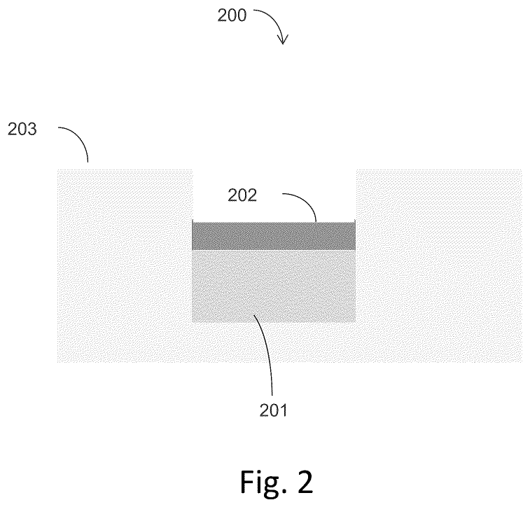

Referring to FIG. 2, described herein is structure 200. The structure 200 comprises a layer 201, an oxidized layer 202 and a second material 203. The layer 201 can comprise a transition metal. In some embodiments, the transition metal comprises molybdenum. In some embodiments, the transition metal comprises tungsten. The oxidized layer 202 comprises native oxide. In other words, the layer 201 has been exposed to air with which the transition metal has reacted and therefore been oxidized. In order to remove the oxidized layer 202, it is then exposed to a volatilization reactant and this way the oxidized layer 202 is removed. The layer 201 below the oxidized layer 202 is not affected by the volatilization reactant. In some embodiments, the method comprises a second layer 203. The second layer 203 comprises a material which is not etched. In other words, the second layer is not oxidized by the oxidation reactant and it is not etched when exposed to the volatilization reactant. In some embodiments, the second layer 203 comprises a dielectric material.

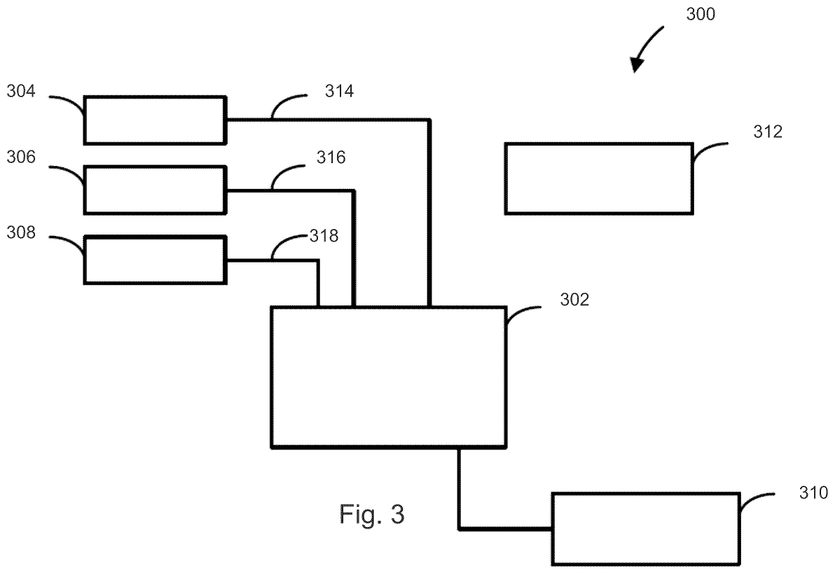

Referring to FIG. 3, further described herein is a system 300 that is constructed and arranged for carrying out an embodiment of a method as described herein.

In the illustrated example, the system 300 includes one or more reaction chambers 302, a oxidation reactant gas source 304, a volatilization reactant gas source 306, a purge gas source 308, an exhaust source 310, and a controller 312. Of course, other gas sources can be present, in some embodiments. For example, a system 300 can comprise all of an oxidation reactant gas source 304, a volatilization reactant gas source 306 source, a purge gas source 308, and further gas sources. The reaction chamber 302 can include any suitable reaction chamber. For simplicity, the system 300 is described referring only to a generic oxidation reactant gas source 304 and a generic volatilization reactant gas source 306.

The oxidation reactant gas source 304 can include a vessel and one or more precursors as described herein-alone or mixed with one or more carrier (e.g., inert) gases. The volatilization reactant gas source 306 can include a vessel and one or more reactants as described herein-alone or mixed with one or more carrier gases. The purge gas source 308 can include one or more purge gases as described herein. Although illustrated with three gas sources 304-308, the system 300 can include any suitable number of gas sources. The gas sources 304-308 can be coupled to reaction chamber 302 via lines 314-318, which can each include flow controllers, valves, heaters, and the like. The exhaust 310 can include one or more vacuum pumps.

The controller 312 includes electronic circuitry and software to selectively operate valves, manifolds, heaters, pumps and other components included in the system 300. Such circuitry and components operate to introduce precursors, reactants, and purge gases from the respective sources 304-308. The controller 312 can control timing of gas pulse sequences, temperature of the substrate and/or reaction chamber, pressure within the reaction chamber, and various other operations to provide proper operation of the system 300. The controller 312 can include control software to electrically or pneumatically control valves to control flow of precursors, reactants and purge gases into and out of the reaction chamber 302. The controller 312 can include modules such as a software or hardware component, e.g., a FPGA or ASIC, which performs certain tasks. A module can advantageously be configured to reside on the addressable storage medium of the control system and be configured to execute one or more processes.

Other configurations of the system 300 are possible, including different numbers and kinds of reactant sources and purge gas sources. Further, it will be appreciated that there are many arrangements of valves, conduits, precursor sources, and purge gas sources that may be used to accomplish the goal of selectively feeding gases into the reaction chamber 302. Further, as a schematic representation of a system, many components have been omitted for simplicity of illustration, and such components may include, for example, various valves, manifolds, purifiers, heaters, containers, vents, and/or bypasses.

During operation of the reactor system 300, substrates, such as semiconductor wafers (not illustrated), are transferred from, e.g., a substrate handling system to reaction chamber 302. Once substrate(s) are transferred to the reaction chamber 302, one or more gases from the gas sources 304-308, such as precursors, reactants, carrier gases, and/or purge gases, are introduced into reaction chamber 302.

Further described herein is a method of selectively depositing a layer. The method comprises providing a substrate to a reaction chamber. The substrate comprises a first surface and a second surface. The method further comprises executing a cyclical deposition process. The cyclical deposition process comprises a plurality of cycles. Ones from the plurality of cycles comprise a deposition sub step and an etching sub step. The deposition sub step comprises contacting the substrate with one or more precursors and reactants to selectively form a deposited layer on the first surface, and not or to a lesser degree on the second surface. The deposition sub step can comprise any suitable deposition technique such as atomic layer deposition or chemical vapor deposition. The etching sub step comprises contacting the substrate with one or more etchants, conversion reactants, volatilization reactants, and/or the like. The etching sub step can comprise any suitable etch such as a continuous etch, a pulsed etch, and an atomic layer etch. The etching sub step can comprise executing an etching process according to an embodiment of the present disclosure. By sequentially and cyclically depositing and etching, selectivity can be improved, e.g. by removal of nuclei from the second surface.

1. A method of etching, comprising
providing a substrate to a reaction chamber, the substrate comprising an etchable layer, the etchable layer comprising transition metal; and
executing a cyclical etching process comprising a plurality of etching cycles,
at least one of the plurality of etching cycles comprises an oxidation reactant pulse that comprises exposing the substrate to an oxidation reactant; and
at least one of the plurality of etching cycles further comprising a volatilization reactant pulse that comprises exposing the substrate to a volatilization reactant,
thereby etching the etchable layer,
wherein the volatilization reactant is free from metals.

2. The method according to claim 1, wherein the substrate further comprises a second layer, and wherein the second layer is not substantially etched during the cyclical etching process, thus selectively etching the etchable layer versus the second layer.

3. The method according to claim 2, wherein the second layer comprises dielectric material.

4. The method according to claim 1, wherein the cyclical etching process is carried out thermally.

5. The method according to claim 1, wherein the oxidation reactant is selected from the group consisting of O₂, O₃ and air.

6. The method according to claim 1, wherein the volatilization reactant comprises a halide.

7. The method according to claim 1, wherein the volatilization reactant comprises chlorine.

8. The method according to claim 1, wherein the volatilization reactant comprises thionyl chloride (SOCl₂).

9. The method according to claim 1, wherein the volatilization reactant comprises phosphorous trichloride (PCl₃).

10. The method according claim 1, wherein the etchable layer comprises metallic transition metal.

11. The method according to claim 10, wherein the transition metal comprises at least one of molybdenum and tungsten.

12. The method according to claim 1, wherein the cyclical etching process is carried out at a temperature of at least 250 to at most 450° C.

13. The method according to claim 1, wherein the volatilization reactant pulse is followed by a by a first purge.

14. The method according to claim 1, wherein the oxidation reactant pulse is followed by a second purge.

15. The method according to claim 1, wherein the etching is atomic layer etching.

16. A method of etching a surface, the method comprising
providing a substrate into a reaction chamber, the surface of the substrate comprising an etchable layer; and
providing a volatilization reactant into the reaction chamber,
wherein the etchable layer comprises MOx, where M is transition metal.

17. The method according to claim 16, wherein the etchable layer comprises native oxide.

18. A system comprising a reaction chamber, a substrate support, and a controller, the controller being configured for causing the system to execute a method according to claim 1.

19. The system according to claim 18, wherein the system does not comprise a plasma source.
